(19) United States
(12) Patent Application Publication
(10) Pub. No.: US 2015/0009715 A1
(43) Pub. Date: Jan. 8, 2015

(54) POWER SAVING CURRENT MEASURING APPARATUS AND POWER CONVERTER USING SAME

(71) Applicant: SOONGSIL UNIVERSITY RESEARCH CONSORTIUM TECHNO-PARK, Seoul (KR)

(72) Inventor: Joung Hu Park, Seoul (KR)

(21) Appl. No.: 14/372,456

(22) PCT Filed: Jan. 15, 2013
(86) PCT No.: PCT/KR2013/000300

§ 371 Date: Jul. 16, 2014

(30) Foreign Application Priority Data
Jan. 25, 2012 (KR) 10-2012-0007375

(51) Int. Cl. H02M 3/335; G01R 1/20; G01R 19/00

(52) U.S. Cl. CPC H02M 3/33546; G01R 19/0092; G01R 1/203
USPC 363/21.1; 363/21.04; 324/713

(57) ABSTRACT

Disclosed is a power saving current measuring apparatus which includes a sensing resistor; a switch that is connected to the sensing resistor in parallel; a controller that controls on and off operations of the switch; and a current measuring unit that measures current flowing in the sensing resistor, wherein when the switch is turned on, the controller controls the current to bypasses the sensing resistor to flow to the switch, and when the switch is turned off, the controller controls the current to flow in the sensing resistor.

### TECHNICAL FIELD

The present invention relates to a power saving current measuring apparatus and a power converter using same, and more particularly, to a technology of reducing unnecessary power consumption in a resistor for sensing current.

### BACKGROUND ART

In general, as a method for measuring current on a load in an arbitrary circuit, there is a method of connecting a separate sensing resistor to the load and measuring current flowing in the sensing resistor. An example according to the related art relating to the technology is disclosed in U.S. Pat. Registration No. 7,135,891.

Unfortunately, in the related art, since only the sensing resistor is simply disposed, when a power is applied to the circuit to operate the circuit, the current continuously flows through the sensing resistor. In such a case, since the current continuously flows in the sensing resistor for a time during which it is not necessary to measure the current as well as a time during which it is necessary to measure the current, unnecessary power loss may be caused in the sensing resistor. In addition, when the sensing resistor is degraded due to the continuous current flow, measuring efficiency may be deteriorated.

### DISCLOSURE

### Technical Problem

An object of the present invention is to provide a power saving current measuring apparatus capable of preventing power loss and improving measuring efficiency by connecting a sensing resistor to a current measuring target and connecting a switch to the sensing resistor in parallel to use the sensing resistor only at a time when it is necessary to measure current.

### Technical Solution

An exemplary embodiment of the present invention provides a power saving current measuring apparatus including a sensing resistor; a switch that is connected to the sensing resistor in parallel; a controller that controls on and off operations of the switch; and a current measuring unit that measures current flowing in the sensing resistor. When the switch is turned on, the controller controls the current to bypasses the sensing resistor to flow to the switch, and when the switch is turned off, the controller controls the current to flow in the sensing resistor.

Further, the controller may control the on and off operations of the switch by a PWM technique.

Furthermore, the apparatus may further include a timing setting unit that sets a current measuring timing of the current measuring unit. The controller may control the on and off operations of the switch in synchronization with the current measuring timing.

Moreover, one end of the sensing resistor may be connected to a ground power supply.

In addition, the switch may be a MOSFET, the sensing resistor may be a resistor between a drain and a source of the MOSFET, and the controller may control a gate voltage of the MOSFET to control the current flowing in the sensing resistor.

Further, the current measuring unit may measure the current in a discrete time for a digital or analog type.

Another exemplary embodiment of the present invention provides a power converter which includes a driving unit that controls on and off operation of a main switch to supply a primary current, a transformer that receives the primary current to output a secondary current depending on a winding ratio between a primary winding and a secondary winding, and a power saving current measuring apparatus that senses the primary current. The power saving current measuring apparatus includes: a sensing resistor that is connected between the main switch connected to the primary winding and a first power supply; a sub-switch that is connected to the sensing resistor in parallel; a second controller that controls on and off operations of the sub-switch; and a current measuring unit that measures current flowing in the sensing resistor.

Furthermore, the driving unit may include a first controller that controls on and off operations of the main switch, and the first controller and the second controller may respectively control the on and off operations of the main switch and the sub-switch by a PWM technique.

Moreover, when the sub-switch is turned on, the second controller may control the current to flow in the sensing resistor, and when the sub-switch is turned off, the second controller may control the current to bypass the sensing resistor to flow to the sub-switch.

In addition, the apparatus may further include a timing setting unit that sets a current measuring timing of the current measuring unit. The first controller and the second controller may control the on and off operations of the switches in synchronization with the current measuring timing.

Furthermore, the switch may be a MOSFET, the sensing resistor may be a resistor between a drain and a source of the MOSFET, the controller may control a gate voltage of the MOSFET to control the current flowing in the sensing resistor, and the first power supply may be a ground power supply.

In addition, the current measuring unit may measure the current in a discrete time for a digital or analog type.

### Advantageous Effects

In accordance with a power saving current measuring apparatus according to the present invention, since a sensing resistor is connected to a current measuring target and a switch is connected to the sensing resistor in parallel, the sensing resistor is used only at the time when it is necessary to measure current, so that it is possible to prevent power loss and to improve measuring efficiency.

### DESCRIPTION OF DRAWINGS

FIG. 1 is a configuration diagram of a power saving current measuring apparatus according to an embodiment of the present invention.

FIG. 2 is a configuration diagram of a power converter using a power saving current measuring apparatus according to another embodiment of the present invention.

FIG. 3 illustrates examples of a current sensing waveform by using the apparatus of FIG. 1.

### BEST MODE

Hereinafter, embodiments of the present invention will be described in detail with reference to the accompanying drawings to allow those skilled in the art to easily implement the embodiments.

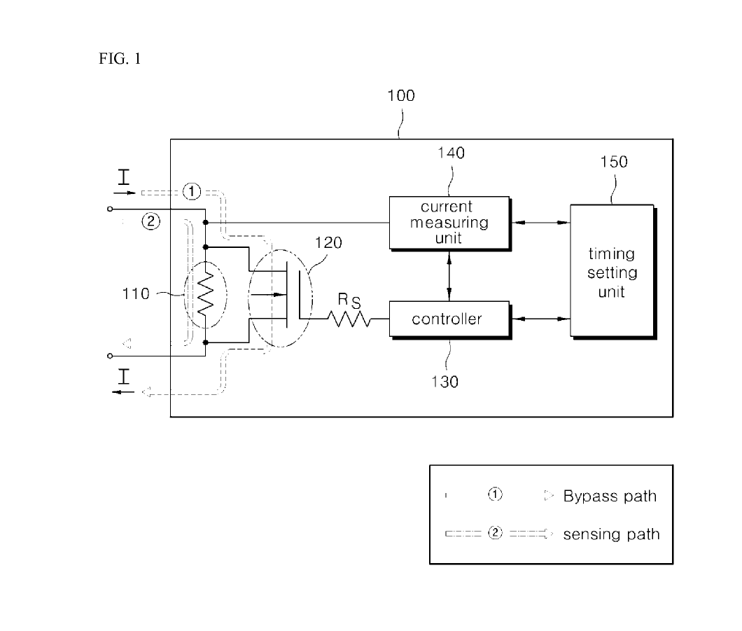

FIG. 1 is a configuration diagram of a power saving current measuring apparatus according to an embodiment of the present invention.

Referring to FIG. 1, a power saving current measuring apparatus 100 according to an embodiment of the present invention includes a sensing resistor 110, a switch 120, a controller 130, a current measuring unit 140, and a timing setting unit 150.

The sensing resistor 110 is a resistor that is connected to a path in which a current to be measured by the power saving current measuring apparatus 100 flows. One end of the sensing resistor 110 may be connected to a ground power supply. The ground power supply means a ground of a typical circuit.

The switch 120 is connected to the sensing resistor 110 in parallel, and is a device that allows current to flow in the sensing resistor 110 or does not allow current to flow in the sensing resistor. For example, when the switch 120 is turned on, the current bypasses the sensing resistor 110 to flow through the switch 120, which is called a bypass path \textcircled{1}. Accordingly, since the current does not flow in the sensing resistor 110, power consumption by the sensing resistor 110 is not caused. When the switch 120 is turned off, the current flows through the sensing resistor 110, which is called a sensing path \textcircled{2}. In such a case, since the current flows in the sensing resistor 110, a voltage is generated, and power consumption is caused.

The controller 130 controls on and off operations of the switch 120. When the switch 120 is turned on, the controller controls the current to bypass the sensing resistor 110 to flow to the switch 120, and when the switch 120 is turned off, the controller controls the current to flow in the sensing resistor 110. Further, the controller 130 may control the on and off operations of the switch 120 by a PWM (Pulse Width Modulation) technique. Furthermore, when the switch 120 is turned on, the controller 130 may control the current to flow through the sensing resistor 110, and when the switch is turned off, the controller may control the current to bypass the sensing resistor 110 to flow to the switch 120. Further, an internal resistor RS may be connected between the switch 120 and the controller 130.

Meanwhile, the switch 120 may be implemented as a MOSFET (not illustrated), and the sensing resistor 110 may be replaced with a resistor between a drain and a source of the MOSFET. In this case, the controller 130 controls a gate voltage of the MOSFET to control the current flowing in the sensing resistor (the resistor between the drain and the source).

The current measuring unit 140 measures the current flowing in the sensing resistor 110. When the switch 120 is turned on, since the current does not flow through the sensing resistor 110, a measured current value is 0, and when the switch 120 is turned off, since the current flows through the sensing resistor 110, a voltage is generated, and a current value is calculated using a preset sensing resistor value. Moreover, the current measuring unit 140 may measure the current in a discrete time for a digital or analog type.

The timing setting unit 150 sets a current measuring timing of the current measuring unit 140, and the current measuring timing may be differently set depending on a setting of a user. The timing setting unit 150 is connected to the current measuring unit 140 and the controller 130 to provide a timing signal for measuring the current. In this case, the controller 130 may control the on and off operations of the switch 120 in synchronization with the current measuring timing, and the current measuring unit 140 may measure the current only for the current measuring time. Accordingly, during a time other than the current measuring time, the current is not allowed to flow in the sensing resistor 110 and the current is not measured, so that it is possible to reduce the power consumption.

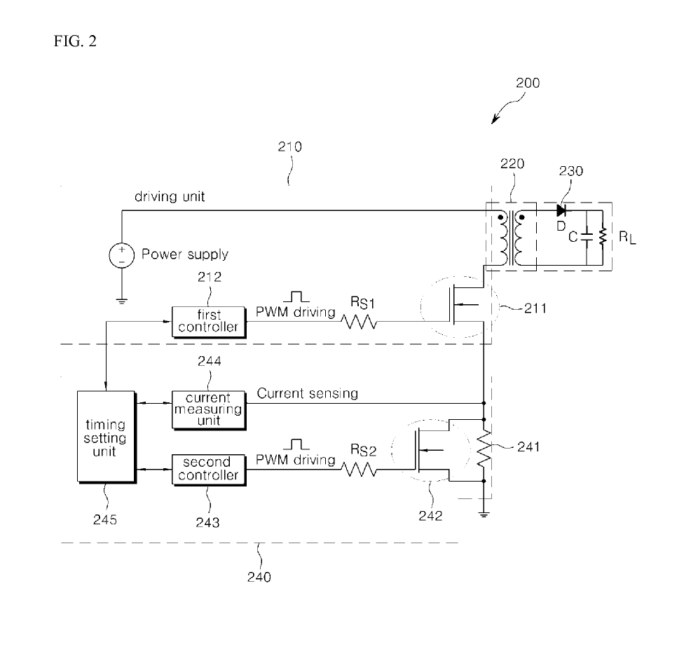

FIG. 2 is a configuration diagram of a power converter using a power saving current measuring apparatus according to another embodiment of the present invention.

Referring to FIG. 2, a power converter using a power saving current measuring apparatus according to another embodiment of the present invention includes a driving unit 210, a transformer 220, an output unit 230, and a power saving current measuring apparatus 240. In general, the power converter 200 may include only the driving unit 210, the transformer 220, and the output unit 230, but may further include the power saving current measuring apparatus 240 in order to control an output by sensing an input current.

The driving unit 210 controls an internal power supply the on and off operations of a main switch 211 to generate a primary current. Here, the turning on or off of the main switch 211 through a first controller 212 is controlled by the PWM (Pulse Width Modulation) technique. In this case, an internal resistor RS1 may be connected between the main switch 211 and the first controller 212.

The transformer 220 receives the primary current from the driving unit 210 to output a secondary current to the output unit 230 depending on a winding ratio between a primary winding and a secondary winding.

The output unit 230 includes a diode D that rectifies the secondary current, a capacitor C that smooths a voltage through the diode D, and a load resistor RL connected to a load.

The configuration of the power converter may be further modified in various manners. Accordingly, the configuration of the present invention is not necessarily limited to the configuration of FIG. 2. In addition, since a detailed operation of the power converter is already variously known, more detailed description thereof will not be presented.

As the power saving current measuring apparatus 240 which is a component for measuring the current, configurations of a sensing resistor 241, a sub-switch 242, a second controller 243, a current measuring unit 244, and a timing setting unit 245 will be described below.

The sensing resistor 241 is connected between the main switch 211 connected to the primary winding and a first power supply. In the present embodiment, the first power supply corresponds to the ground power supply, but the present invention is not necessarily limited thereto.

The sub-switch 241 is connected to the sensing resistor 242 in parallel. The sub-switch 241 may be implemented as a semiconductor switch such as a transistor that can be turned on or off

The second controller 243 controls on and off operations of the sub-switch 241. Similarly to the first controller 212, the second controller 243 controls the on and off operations of the sub-switch 241 by the PWM technique. Here, it is appreciated that the controlling of the on and off operations of the respective switches 211 and 241 includes controlling on and off cycles and times.

When the sub-switch 241 is turned on, the second controller 243 controls the current to flow in the sensing resistor 242. Meanwhile, when the sub-switch 242 is turned off, the second controller controls the current to bypass the sensing resistor 242 to flow to the sub-switch 241, so that the current is not allowed to flow in the sensing resistor 241. In such a case, an internal resistor RS2 may be connected between the sub-switch 242 and the second controller 243.

Meanwhile, the sub-switch 241 may be implemented as a MOSFET (not illustrated), and the sensing resistor 241 may be replaced with a resistor between a drain and a source of the MOSFET. In this case, the second controller 243 may control a gate voltage of the MOSFET to control the current flowing in the sensing resistor (the resistor between the drain and the source).

The current measuring unit 244 is a part that measures the current flowing in the sensing resistor 241. As described above, the current measuring unit 244 measures the current according to on the controlling operation of the PWM of the second controller 243 only when the sub-switch 241 is turned on.

The current measuring unit 244 measures the current in a discrete time for a digital or analog type. That is, the present invention is applicable to all cases (for example, analog/digital controllers) where the discrete time is used.

As mentioned above, in the present invention, in order to accurately measure the current flowing in the main switch 211 of the power converter 200, the sub-switch 242 is connected to the sensing resistor 241 connected to the main switch 211 in parallel, and the current is allowed to flow in the sensing resistor 241 only for a time during which it is necessary to measure the current.

If the sub-switch 242 is not included, the current flows in the sensing resistor 241 in the whole time, and the current is continuously sensed through the sensing resistor 241.

In the present invention, by controlling the on and off operations of the sub-switch 242, the current is allowed to bypass through the sub-switch 242 for a time during which the current is not measured, so that a rated power applied to the sensing resistor 241 is decreased. As a result, it is possible to reduce the power consumption in the sensing resistor 241.

Further, since the sensing resistor 241 is used only when it is necessary to measure the current, it is possible to prevent the sensing resistor 241 from being degraded, and it is possible to expand lifespan thereof As a result, it is possible to improve current measuring efficiency.

Meanwhile, the timing setting unit 245 is connected to the first controller 242, the second controller 243 and the current measuring unit 244. The timing setting unit 245 synchronizes switch timings of the sub-switch 242 and the main switch 211 each other to allow the second controller 243 to be operated in interconnection with the first controller 242. Moreover, the current measuring unit 244 calculates a current value only when the current flows in the sensing resistor 241 according to the switch timings, so that it is possible to reduce the power consumption.

Accordingly, it is possible to control the on and off operations by the second controller 243 such that the current in the main switch 211 can be measured only at a time when the signal passes through the main switch 211 by controlling the on and off operations by the first controller 242. In contrast, since it is not necessary to measure the current when the signal does not pass through the main switch 211, the on and off operations by the second controller 243 is controlled.

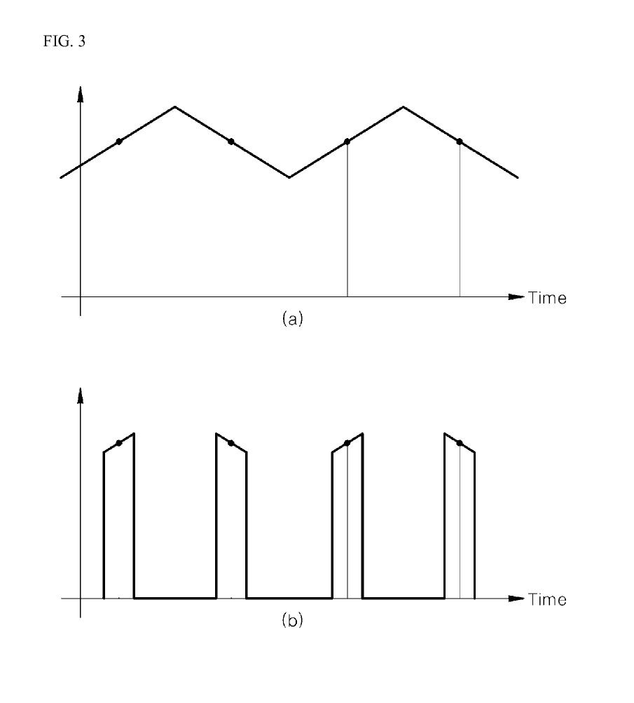

FIG. 3 illustrates examples of a current sensing waveform by using the apparatus of FIG. 1. Here, a horizontal axis represents a time, and a vertical axis represents a sensed current value.

(a) of FIG. 3 illustrates a case where the sub-switch 242 exists or an existing case where the sub-switch 242 is constantly turned on. In such a case, in a structure in which the current constantly flows through the sensing resistor 241, a controller discretely receives a current value. However, the sensing resistor continuously measures the current value to measure continuously the current, so that the power consumption may be increased.

However, (b) of FIG. 3 illustrates a case where on and off cycles and times of the sub-switch 242 are controlled by the PWM technique. The current flows in the sensing resistor 241 only when the sub-switch 242 is turned on, so that the current is sensed. When the sub-switch 242 is turned off, since the current does not flow in the sensing resistor 241, the current is not sensed. In this case, the current measuring time is intermittent, and it is possible to reduce the power consumption in the sensing resistor 241.

The configurations of FIG. 3 are merely examples for helping description of the present invention, and the sensed current waveform is not necessarily limited thereto.

In accordance with the power saving current measuring apparatus and the power converter using same according to the embodiment of the present invention, the sensing resistor is connected to the current measuring target and the switch is connected to the sensing resistor in parallel, so that the sensing resistor is used only at the time when it is necessary to measure the current. Accordingly, it is possible to prevent power loss, and it is possible to improve measuring efficiency.

Although the present invention has been described in connection with the embodiments illustrated in the drawings, the embodiments are merely examples. It should be appreciated to those skilled in the art that various modifications and equivalents to these embodiments are possible. Therefore, the technical scope of the present invention should be decided by the technical spirit of the appended claims.

1. A power saving current measuring apparatus comprising:
a sensing resistor;
a switch that is connected to the sensing resistor in parallel;
a controller that controls on and off operations of the switch; and
a current measuring unit that measures current flowing in the sensing resistor,
wherein when the switch is turned on, the controller controls the current to bypasses the sensing resistor to flow to the switch, and
when the switch is turned off, the controller controls the current to flow in the sensing resistor.

2. The power saving current measuring apparatus of claim 1, wherein the controller controls the on and off operations of the switch by a PWM technique.

3. The power saving current measuring apparatus of claim 1, further comprising:
a timing setting unit that sets a current measuring timing of the current measuring unit,
wherein the controller controls the on and off operations of the switch in synchronization with the current measuring timing.

4. The power saving current measuring apparatus of claim 1, wherein one end of the sensing resistor is connected to a ground power supply.

5. The power saving current measuring apparatus of claim 1,
wherein the switch is a MOSFET,
the sensing resistor is a resistor between a drain and a source of the MOSFET, and
the controller controls a gate voltage of the MOSFET to control the current flowing in the sensing resistor.

6. The power saving current measuring apparatus of claim 1, wherein the current measuring unit measures the current in a discrete time for a digital or analog type.

7. The power saving current measuring apparatus of claim 2, wherein the current measuring unit measures the current in a discrete time for a digital or analog type.

8. The power saving current measuring apparatus of claim 3, wherein the current measuring unit measures the current in a discrete time for a digital or analog type.

9. The power saving current measuring apparatus of claim 4, wherein the current measuring unit measures the current in a discrete time for a digital or analog type.

10. The power saving current measuring apparatus of claim 5, wherein the current measuring unit measures the current in a discrete time for a digital or analog type.

11. A power converter which includes a driving unit that controls on and off operation of a main switch to supply a primary current, a transformer that receives the primary current to output a secondary current depending on a winding ratio between a primary winding and a secondary winding, and a power saving current measuring apparatus that senses the primary current,
wherein the power saving current measuring apparatus includes:
a sensing resistor that is connected between the main switch connected to the primary winding and a first power supply;
a sub-switch that is connected to the sensing resistor in parallel;
a second controller that controls on and off operations of the sub-switch; and
a current measuring unit that measures current flowing in the sensing resistor.

12. The power converter of claim 11,
wherein the driving unit includes a first controller that controls on and off operations of the main switch, and
the first controller and the second controller respectively control the on and off operations of the main switch and the sub-switch by a PWM technique.

13. The power converter of claim 12,
wherein when the sub-switch is turned on, the second controller controls the current to flow in the sensing resistor, and
when the sub-switch is turned off, the second controller controls the current to bypass the sensing resistor to flow to the sub-switch.

14. The power converter of claim 12, further comprising:
a timing setting unit that sets a current measuring timing of the current measuring unit,
wherein the first controller and the second controller control the on and off operations of the switches in synchronization with the current measuring timing.

15. The power converter of claim 11,
wherein the switch is a MOSFET,
the sensing resistor is a resistor between a drain and a source of the MOSFET,
the controller controls a gate voltage of the MOSFET to control the current flowing in the sensing resistor, and
the first power supply is a ground power supply.

16. The power converter of claim 11, wherein the current measuring unit measures the current in a discrete time for a digital or analog type.

17. The power converter of claim 12, wherein the current measuring unit measures the current in a discrete time for a digital or analog type.

18. The power converter of claim 13, wherein the current measuring unit measures the current in a discrete time for a digital or analog type.

19. The power converter of claim 14, wherein the current measuring unit measures the current in a discrete time for a digital or analog type.

20. The power converter of claim 15, wherein the current measuring unit measures the current in a discrete time for a digital or analog type.
